(19) United States
(12) Patent Application Publication
(10) Pub. No.: US 2017/0051405 A1
(43) Pub. Date: Feb. 23, 2017

(54) METHOD FOR FORMING SIN OR SICN FILM IN TRENCHES BY PEALD

(71) Applicant: ASM IP Holding B.V., Almere (NL)

(72) Inventors: Atsuki Fukazawa, Tokyo (JP); Hideaki Fukuda, Tokyo (JP)

(21) Appl. No.: 14/829,565

(22) Filed: Aug. 18, 2015

(51) Int. Cl. C23C 16/455; C23C 16/44; C23C 16/505; C23C 16/34

(52) U.S. Cl. CPC C23C 16/45536; C23C 16/345; C23C 16/347; C23C 16/4408; C23C 16/45553; C23C 16/505

(57) ABSTRACT

A method for forming a SiN or SiCN film in a trench on a substrate by plasma-enhanced atomic layer deposition (PEALD) conducts one or more process cycles, each process cycle including: (i) feeding a precursor in a pulse to a reaction space where the substrate is place, said precursor having a Si—N—Si bond in its skeletal structure to which at least one halogen group is attached; and (ii) applying RF power to the reaction space in the presence of a reactant gas and in the absence of any precursor to form a monolayer constituting a SiN or SiCN film.

### BACKGROUND

Field of the Invention

The present invention relates generally to a method forming a SiN or SiCN film in trenches on a substrate by plasma-enhanced atomic layer deposition (PEALD).

Related Art

When a SiN or SiCN film is formed by PEALD using a precursor having a nitrogen atom in the center of its skeletal structure where a terminal group of Si is terminated with a hydrogen or hydrocarbon, a sidewall or bottom surface coverage of the film deposited in a trench of a substrate is often insufficient due to its weak chemisorption properties. This may be because the precursor has only a Si—H bond as a chemisorption site. Among precursors having a nitrogen atom in the center of its skeletal structure, a compound having a silylamine structure is beneficial because the precursor has a Si—N—Si bond, and the skeleton of the deposited film can be derived from the precursor itself, and thus, the deposition of the film need not be dependent upon reaction with a reactant gas. However, the precursor still has a problem of poor sidewall and bottom surface coverage.

Any discussion of problems and solutions in relation to the related art has been included in this disclosure solely for the purposes of providing a context for the present invention, and should not be taken as an admission that any or all of the discussion was known at the time the invention was made.

### SUMMARY

In some embodiments, a precursor is a silylamine or silazane compound having a bond where N is sandwiched by Si such as a Si—N—Si bond or a

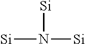

bond, wherein a halogen group is incorporated at at least one terminal group attached to Si in a SiN or SiCN film (in this disclosure, the SiN and SiCN include SiNH and SiCNH). As a result, a sidewall coverage and a bottom surface coverage of a film deposited in a trench of a substrate can be increased to 90% or higher. Conventionally, reaction groups and terminal groups of a precursor are constituted by mostly alkylamine or hydrogen, resulting in poor step coverage. When using a halogen group as a terminal group in a precursor, a Si—N bond can readily be incorporated in a film via substitution reaction since a halogen group has superior reactivity for substitution reaction with NH₃ or H₂/N₂, resulting in superior step coverage. When the precursor has a bond wherein two or three Si atoms are attached to N, at least one of which Si atoms is terminated by a halogen group, nitridization of the film can be accomplished without highly depending on a plasma. If nitridization depends predominantly on a plasma as in conventional precursors, not only step coverage but also film quality will often suffer, e.g., film quality on a blanket surface (a top surface in which a trench is formed) and a bottom surface will often be different, and film quality on a sidewall will often be unsatisfactory.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1A is a schematic representation of a PEALD (plasma-enhanced atomic layer deposition) apparatus for depositing a dielectric film usable in an embodiment of the present invention.

FIG. 1B illustrates a schematic representation of switching flow of an inactive gas and flow of a precursor gas usable in an embodiment of the present invention.

FIG. 2 illustrates a precursor supply system using a flow-pass system (FPS) according to an embodiment of the present invention.

FIG. 3 illustrates a precursor supply system using an auto-pressure regulator (APR) according to an embodiment of the present invention.

FIG. 4 illustrates a precursor supply system using a bottle-out control system (BTO) according to an embodiment of the present invention.

FIG. 5 illustrates a precursor supply system using an APR with a BTO according to an embodiment of the present invention.

FIG. 6 illustrates a precursor supply system using a mass flow controller (MFC) according to an embodiment of the present invention.

FIG. 7 illustrates a PEALD process sequence according to an embodiment of the present invention.

### DETAILED DESCRIPTION OF EMBODIMENTS

In this disclosure, “gas” may include vaporized solid and/or liquid and may be constituted by a single gas or a mixture of gases. In this disclosure, a process gas introduced to a reaction chamber through a showerhead may be comprised of, consist essentially of, or consist of a precursor gas and an additive gas. The precursor gas and the additive gas are typically introduced as a mixed gas or separately to a reaction space. The precursor gas can be introduced with a carrier gas such as a noble gas. The additive gas may be comprised of, consist essentially of, or consist of a reactant gas and a dilution gas such as a noble gas. The reactant gas and the dilution gas may be introduced as a mixed gas or separately to the reaction space. A precursor may be comprised of two or more precursors, and a reactant gas may be comprised of two or more reactant gases. The precursor is a gas chemisorbed on a substrate and typically containing a metalloid or metal element which constitutes a main structure of a matrix of a dielectric film, and the reactant gas for deposition is a gas reacting with the precursor chemisorbed on a substrate when the gas is excited to fix an atomic layer or monolayer on the substrate. “Chemisorption” refers to chemical saturation adsorption. A gas other than the process gas, i.e., a gas introduced without passing through the showerhead, may be used for, e.g., sealing the reaction space, which includes a seal gas such as a noble gas. In some embodiments, “film” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation processes or sequence, and/or functions or purposes of the adjacent films or layers.

Further, in this disclosure, the article “a” or “an” refers to a species or a genus including multiple species unless specified otherwise. The terms “constituted by” and “having” refer independently to “typically or broadly comprising”, “comprising”, “consisting essentially of”, or “consisting of” in some embodiments. Also, in this disclosure, any defined meanings do not necessarily exclude ordinary and customary meanings in some embodiments.

Additionally, in this disclosure, any two numbers of a variable can constitute a workable range of the variable as the workable range can be determined based on routine work, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments.

In the present disclosure where conditions and/or structures are not specified, the skilled artisan in the art can readily provide such conditions and/or structures, in view of the present disclosure, as a matter of routine experimentation. In all of the disclosed embodiments, any element used in an embodiment can be replaced with any elements equivalent thereto, including those explicitly, necessarily, or inherently disclosed herein, for the intended purposes. Further, the present invention can equally be applied to apparatuses and methods.

The embodiments will be explained with respect to preferred embodiments. However, the present invention is not limited to the preferred embodiments.

Some embodiments provide a method for forming a SiN or SiCN film in a trench on a substrate by plasma-enhanced atomic layer deposition (PEALD) by conducting one or more process cycles, each process cycle comprising: (i) feeding a precursor in a pulse to a reaction space where the substrate is placed, said precursor having a Si—N—Si bond in its skeletal structure to which at least one halogen group is attached; and (ii) applying RF power to the reaction space in the presence of a reactant gas and in the absence of any precursor to form a monolayer constituting a SiN or SiCN film. The SiN film is constituted by at least elements Si and N and typically H. In some embodiments, the film can include impurities, negligible elements, and undetectable elements without being expressly so indicated. The detectable amount varies depending on the composition analysis method. For example, an element such as carbon in a film may not be detected by Rutherford backscattering Spectrometry (RBS) and Hydrogen Forward Scattering (HFS) if the content of carbon is 5 atomic % or less. However, Secondary Ion Mass Spectrometry (SIMS) may be able to detect such a low content of carbon. For example, a film which is considered to be a film of SiNH according to RBS/HFS analysis may be a film of SiCNH according to SIMS analysis. In this disclosure, unless otherwise specified, the chemical formula of a film is determined based on a composition analysis by RBS/HFS.

In some embodiments, the trench has a width of 10 to 50 nm (typically 15 to 30 nm), a length of 10 to 50 nm (typically 15 to 30 nm), a depth of 30 to 200 nm (typically 50 to 150 nm), and an aspect ratio of 3 to 20 (typically 3 to 10).

In some embodiments, the SiN or SiCN film can be used as an etching stopper, low-k spacer, or gap-filler.

In some embodiments, each process cycle further comprises a purging step between steps (i) and (ii), and between steps (ii) and (i) if the process cycle is repeated.

In some embodiments, the Si—N—Si bond of the precursor is a

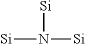

bond. In some embodiments, the precursor is one or more compounds selected from the group consisting of:

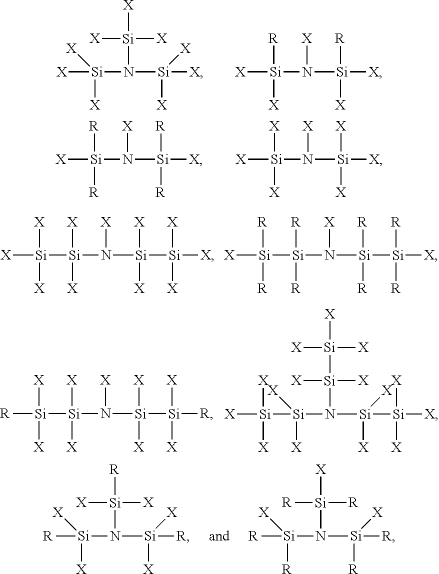

wherein X is H, Cl, F, I, or Br, provided that at least one X in each compound is Cl, F, I, or Br; and R is a chained or cyclic hydrocarbon or nitro hydrocarbon (with, e.g., 1 to 4 carbons).

In some embodiments, the number of halogen group is 1, 2, 3, 4, 5, or 6 (e.g., 2 to 4). In some embodiments, the precursor is trischlorotrisilylamine, monochlorotorisilyaamine, singly or in combination of two or more of the foregoing.

In some embodiments, the precursor is fed in a pulse to the reaction space using a flow-pass system (FPS), auto-pressure regulator (APR), a bottle-out control system (BTO), or mass flow controller (MFC), which will be explained later.

In some embodiments, the reactant gas is one or more gases selected from the group consisting of H₂, NH₃, N₂, NxHy (x and y are integers), and NxCyHz (x, y, and z are integers). In some embodiments, the reactant gas is a mixture of N₂ and H₂, or NH₃. In some embodiments, the reactant gas is fed continuously to the reaction space throughout each process cycle, where the reactant gas and the precursor are not reactive in the absence of a plasma. Continuous flow is beneficial to increase throughput.

In some embodiments, the carrier gas and/or dilution gas is used which is at least one noble gas selected from rare gases such as Ar, He, Kr, and Xe. In some embodiments, a noble gas is continuously fed to the reaction space throughout the process cycle.

In some embodiments, the method further comprises exposing the SiN or SiCN film on the substrate to a hydrogen-containing plasma (without feeding any precursor or after purging all precursor(s)) after the PEALD process, to remove a halogen group, if any, remaining in the SiN or SiCN film. In some embodiments, each process cycle further comprises exposing the monolayer on the substrate to a hydrogen-containing plasma (without feeding any precursor or after purging all precursor(s)) to remove a halogen group, if any, remaining in the monolayer. It is preferred that the final film contains substantially no halogen elements or an insignificant amount of halogen elements. In some embodiments, the gas used for the hydrogen-containing plasma is hydrogen, ammonium, or saturated hydrocarbon such as dimethylamine, or a mixture of the foregoing.

In some embodiments, a sidewall coverage and a bottom coverage are 90% or higher, wherein the sidewall coverage is defined as a ratio of thickness of film on a sidewall of the trench to thickness of film on a blanket surface of the trench, and the bottom coverage is defined as a ratio of thickness of film on a bottom of the trench to thickness of film on the blanket surface of the trench.

The process sequences according to embodiments are explained below. A skilled artisan will be able to modify these sequences according to the target multi-element film based on this disclosure and routine experimentation. In this disclosure, the word “continuously” refers to at least one of the following: without breaking a vacuum, without being exposed to air, without opening a chamber, as an in-situ process, without interruption as a step in sequence, without changing process conditions, and without causing chemical changes on a substrate surface between steps, depending on the embodiment. In some embodiments, an auxiliary step such as a delay between steps or other step immaterial or insubstantial in the context does not count as a step, and thus, the word “continuously” does not exclude an intervening auxiliary step.

FIG. 7 illustrates a PEALD process sequence according to an embodiment, wherein the width of each column does not necessarily represent the actual time length, and a raised level of the line in each row represents an ON-state whereas a bottom level of the line in each row represents an OFF-state.

The deposition cycle includes steps of feeding a precursor to a reaction zone, purging the reaction zone, applying RF power to the reaction zone, and purging the reaction zone in this order, wherein a purge/carrier gas is supplied continuously to the reaction zone throughout the entire steps of deposition cycle, and a reactant gas for deposition is supplied continuously to the reaction zone throughout the steps of deposition cycle except for the step of purging after applying RF power. In the deposition cycle, steps of feeding the precursor, purging the reaction zone, applying RF power to the reaction zone, and purging the reaction zone can be repeated p times (p is an integer of 5 to 5,000, typically 10 to 2,000), depending on the target compositions and quality of the film, etc., although repeating is not required. The film thickness may be in a range of 0.5 to 200 nm, typically 3 to 50 nm, depending on the target use, etc.

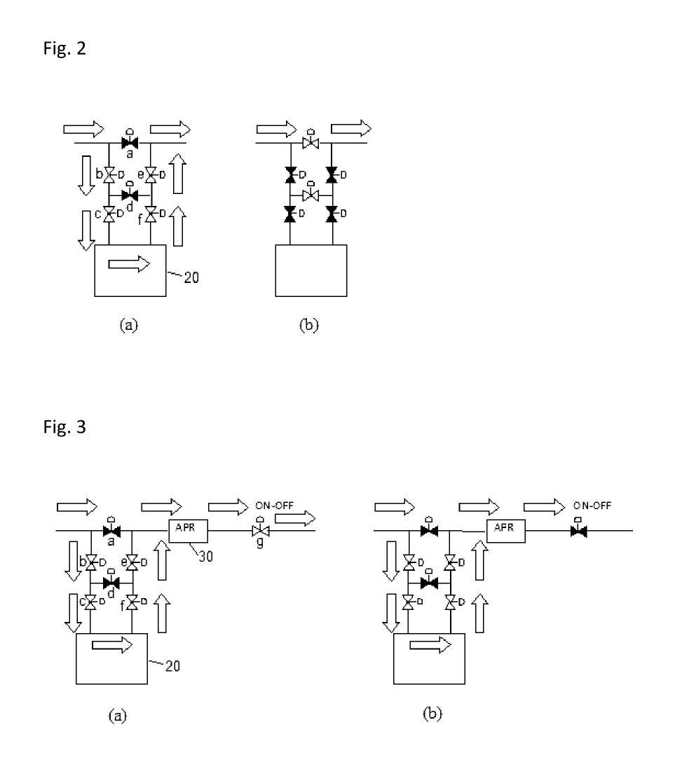

The precursor is fed in a pulse to the reaction space using a flow-pass system (FPS), auto-pressure regulator (APR), a bottle-out control system (BTO), or mass flow controller (MFC). FIG. 2 illustrates a precursor supply system using a flow-pass system (FPS) according to an embodiment of the present invention (black valves indicate that the valves are closed). As shown in (a) in FIG. 2, when feeding a precursor to a reaction chamber (not shown), first, a carrier gas such as Ar (or He) flows through a gas line with valves b and c, and then enters a bottle (reservoir) 20. The carrier gas flows out from the bottle 20 while carrying a precursor gas in an amount corresponding to a vapor pressure inside the bottle 20, and flows through a gas line with valves f and e, and is then fed to the reaction chamber together with the precursor. In the above, valves a and d are closed. When feeding only the carrier gas (noble gas) to the reaction chamber, as shown in (b) in FIG. 2, the carrier gas flows through the gas line with the valve a while bypassing the bottle 20. In the above, valves b, c, e, and fare closed.

FIG. 3 illustrates a precursor supply system using an auto-pressure regulator (APR) according to an embodiment of the present invention. As shown in (a) in FIG. 3, when feeding a precursor to a reaction chamber (not shown), first, a carrier gas flows through a gas line with valves b and c, and then enters a bottle 20. The carrier gas flows out from the bottle 20 while carrying a precursor gas in an amount corresponding to a vapor pressure inside the bottle 20, and flows through a gas line with valves f and e, and is then fed to the reaction chamber together with the precursor through an auto-pressure regulator (APR) 30 and a valve g provided in a gas line upstream of the reaction chamber. In the above, valves a and d are closed. Valve g is an on-off valve, and when preventing the precursor from entering into the reaction chamber, as shown in (b) in FIG. 3, valve g is closed so that neither the precursor nor the carrier gas is fed to the reaction chamber.

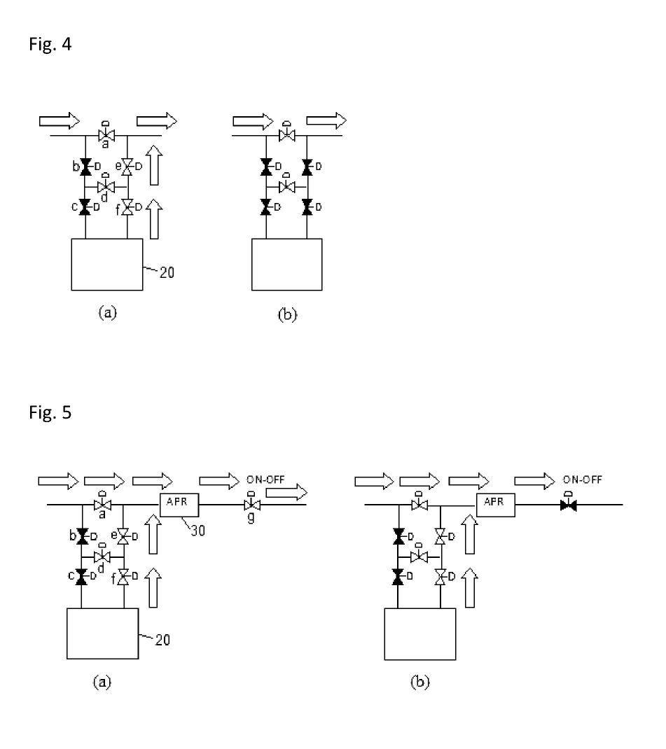

FIG. 4 illustrates a precursor supply system using a bottle-out control system (BTO) according to an embodiment of the present invention. As shown in (a) in FIG. 4, when a carrier gas flows through a gas line with a valve a to a reaction chamber (not shown) without passing through a bottle 20, a precursor gas enters into a stream of the carrier gas passing through the gas line where a gas line from the bottle 20 meets the gas line through which the carrier gas flows, and the carrier gas carries the precursor therefrom and is then fed to the reaction chamber together with the precursor. In the above, valves b and c are closed, and valves e and f are open so that when the vapor pressure inside the bottle 20 is higher than the pressure of the carrier gas passing through the gas line, the precursor flows from the bottle 20 and enters into the stream of the carrier gas. When feeding only the carrier gas to the reaction chamber, as shown in (b) in FIG. 4, the carrier gas flows through a gas line and passes through valve a while bypassing the bottle 20. In the above, valves b, c, e, and f are closed.

FIG. 5 illustrates a precursor supply system using an APR with a BTO according to an embodiment of the present invention. As shown in (a) in FIG. 5, when a carrier gas flows through a gas line with a valve a to a reaction chamber (not shown) without passing through a bottle 20, a precursor gas enters into a stream of the carrier gas passing through the gas line where a gas line from the bottle 20 meets the gas line through which the carrier gas flows, and the carrier gas carries the precursor therefrom and passes through an APR 30 and a valve g together with the precursor, and is then fed to the reaction chamber together with the precursor. In the above, valves b and c are closed, and valves e and f are open so that when the vapor pressure inside the bottle 20 is higher than the pressure of the carrier gas passing through the gas line, the precursor flows from the bottle 20 and enters into the stream of the carrier gas. Valve g is an on-off valve, and when preventing the precursor from entering into the reaction chamber, as shown in (b) in FIG. 5, valve g is closed so that neither the precursor nor the carrier gas is fed to the reaction chamber.

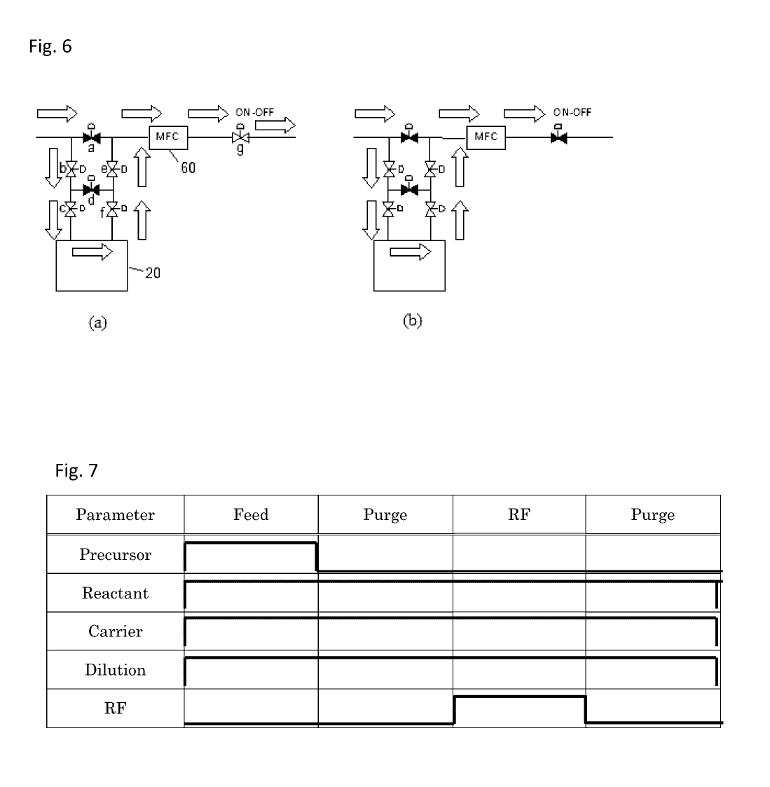

FIG. 6 illustrates a precursor supply system using a mass flow controller (MFC) according to an embodiment of the present invention. As shown in (a) in FIG. 6, when feeding a precursor to a reaction chamber (not shown), first, a carrier gas flows through a gas line with valves b and c, and then enters into a bottle 20. The carrier gas flows out from the bottle 20 while carrying a precursor gas in an amount corresponding to a vapor pressure inside the bottle 20, and flows through a gas line with valves f and e, and is then fed to the reaction chamber together with the precursor through a mass flow controller (MFC) 60 and a valve g provided in a gas line upstream of the reaction chamber. In the above, valves a and d are closed. Valve g is an on-off valve, and when preventing the precursor from entering the reaction chamber, as shown in (b) in FIG. 6, valve g is closed so that neither the precursor nor the carrier gas is fed to the reaction chamber.

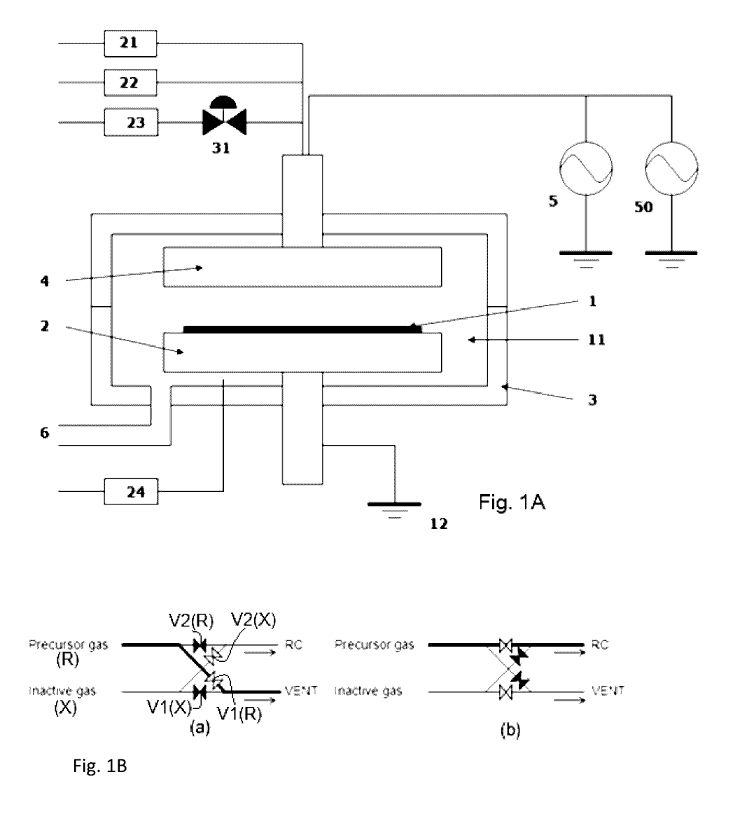

In FIGS. 3, 5, and 6, valve g is used to switch feeding of the precursor and non-feeding of the precursor, wherein the carrier gas flow is also stopped when the precursor flow is stopped. However, the precursor (any gaseous precursor) can be supplied in a pulse using a carrier gas which is continuously supplied. This can be accomplished by, for example, a gas supply system illustrated in FIG. 1B. FIG. 1B illustrates a schematic representation of such a switching flow system. In (a) in FIG. 1B, valves V1 (X) and V2 (R) are closed, and valves V1 (R) and V2 (X) are open, so that a precursor gas flows to a vent via valve V1 (R), and an inactive gas flows to a reactor via valve V2 (X). In (b) in FIG. 1B, by simultaneously closing valves V1 (R) and V2 (X) and opening valves V1 (X) and V2 (R), the precursor gas is instantly directed to flow to the reactor, and the inactive gas is instantly directed to flow to the vent, without substantial changes in the flow rate while maintaining continuous flows. The vent can be set downstream of an exhaust, for example.

In some embodiments, the deposition cycle may be performed by PEALD, one cycle of which is conducted under conditions shown in Table 1 below.

TABLE 1
(the numbers are approximate)
Conditions for Deposition Cycle

| | |
|---|---|
| Substrate temperature | 100 to 500° C. (preferably 200 to 400° C.) |
| Pressure | 50 to 3000 Pa (preferably 200 to 1000 Pa) |
| Precursor pulse | 0.1 to 1 sec (preferably 0.1 to 0.5 sec) |
| Precursor purge | 0.5 to 2 sec (preferably 0.5 to 1 sec) |
| Flow rate of reactant | 100 to 2000 sccm (preferably 500 to |
| | 1000 sccm) for N₂; |
| | 100 to 2000 sccm (preferably 500 to |
| | 1000 sccm) for H_{2;} |
| | (N2/H2 = 100-2000/100-2000, preferably |
| | 500-1000/500-1000) |
| | 100 to 4000 sccm (preferably 1000 to |
| | 2000 sccm) for NH₃ |
| Carrier gas | 1000 to 4000 sccm (preferably 1500 to |
| | 3000 sccm) |
| Dilution gas | 100 to 3000 sccm (preferably 500 to |
| | 1500 sccm) |
| RF power (13.56 MHz) | 50 to 1000 W (preferably 100 to 400 W) |
| for a 300-mm wafer | |
| RF power pulse | 0.5 to 10 sec (preferably 1 to 5 sec) |
| Purge | 0.1 to 2 sec (preferably 0.2 to 1 sec) |
| Growth rate per cycle | 0.01 to 0.1 nm/cycle |

The precursor is typically provided with the aid of a carrier gas. Since ALD is a self-limiting adsorption reaction process, the number of deposited precursor molecules is determined by the number of reactive surface sites and is independent of the precursor exposure after saturation, and a supply of the precursor is such that the reactive surface sites are saturated thereby per cycle. A plasma for deposition may be generated in situ, for example, in an ammonia gas that flows continuously throughout the deposition cycle. In other embodiments the plasma may be generated remotely and provided to the reaction chamber.

As mentioned above, each pulse or phase of each deposition cycle is preferably self-limiting. An excess of reactants is supplied in each phase to saturate the susceptible structure surfaces. Surface saturation ensures reactant occupation of all available reactive sites (subject, for example, to physical size or “steric hindrance” constraints) and thus ensures excellent step coverage. In some embodiments the pulse time of one or more of the reactants can be reduced such that complete saturation is not achieved and less than a monolayer is adsorbed on the substrate surface.

In some embodiments, the SiN or SiCN film is treated with a hydrogen-containing plasma by incorporating a treatment into the deposition cycle or by conducting a treatment as a post-deposition treatment under conditions shown in Table 2 below. By way of the hydrogen-containing plasma treatment, impurities such as halogen groups remaining in the film or the like can be removed to the extent that the content of halogen component is 1 atomic % or less in the film.

TABLE 2
(the numbers are approximate)
Conditions for Post-Deposition Treatment

| | |
|---|---|
| Susceptor temperature | Same as in deposition cycle |
| Pressure | Same as in deposition cycle |
| Flow rate of treatment gas | 100 to 2000 sccm (preferably 500 to |
| | 1000 sccm) |
| Carrier gas (continuous) | Same as in deposition cycle |
| Dilution gas (continuous) | Same as in deposition cycle |
| RF power (13.56 MHz) for a | 50 to 1000 W (preferably 100 to 400 W) |
| 300-mm wafer | |
| Duration of Treatment | 1 to 60 sec (preferably 1 to 10 sec) |
| Frequency of the cycles | Every after deposition of 3 nm, 5 nm, |
| | 7 nm, or 10 nm |

The process cycle can be performed using any suitable apparatus including an apparatus illustrated in FIG. 1A, for example. FIG. 1A is a schematic view of a PEALD apparatus, desirably in conjunction with controls programmed to conduct the sequences described below, usable in some embodiments of the present invention. In this figure, by providing a pair of electrically conductive flat-plate electrodes 4, 2 in parallel and facing each other in the interior 11 of a reaction chamber 3, applying HRF power (13.56 MHz or 27 MHz) 5 and LRF power (5 MHz or less, 400 kHz-500 kHz) 50 to one side, and electrically grounding the other side 12, a plasma is excited between the electrodes. A temperature regulator is provided in a lower stage 2 (the lower electrode), and a temperature of a substrate 1 placed thereon is kept constant at a given temperature. The upper electrode 4 serves as a shower plate as well, and reaction gas and rare gas are introduced into the reaction chamber 3 through a gas flow controller 23, a pulse flow control valve 31, and the shower plate. Additionally, in the reaction chamber 3, an exhaust pipe 6 is provided, through which gas in the interior 11 of the reaction chamber 3 is exhausted. Additionally, the reaction chamber is provided with a seal gas flow controller 24 to introduce seal gas into the interior 11 of the reaction chamber 3 (a separation plate for separating a reaction zone and a transfer zone in the interior of the reaction chamber is omitted from this figure). In some embodiments, the deposition of multi-element film and surface treatment are performed in the same apparatus such as that described above, so that all the steps can continuously be conducted without exposing the substrate to air or other oxygen-containing atmosphere. In some embodiments, a remote plasma unit can be used for exciting a gas.

In some embodiments, in the apparatus depicted in FIG. 1A, in place of the pulse flow control valve 31, the system of switching flow of an inactive gas and flow of a precursor gas illustrated in FIG. 1B (described earlier), can be used.

A skilled artisan will appreciate that the apparatus includes one or more controller(s) (not shown) programmed or otherwise configured to cause the deposition and reactor cleaning processes described elsewhere herein to be conducted. The controller(s) are communicated with the various power sources, heating systems, pumps, robotics and gas flow controllers or valves of the reactor, as will be appreciated by the skilled artisan.

The present invention is further explained with reference to working examples below. However, the examples are not intended to limit the present invention. In the examples where conditions and/or structures are not specified, the skilled artisan in the art can readily provide such conditions and/or structures, in view of the present disclosure, as a matter of routine experimentation. Also, the numbers applied in the specific examples can be modified by a range of at least ±50% in some embodiments, and the numbers are approximate.

### EXAMPLES

A SiN or SiCN film was formed on a Si substrate (Φ300 mm) having trenches with an aspect ratio of 3 (a width of 35 nm) by PEALD using a sequence illustrated in FIG. 7, one cycle of which was conducted under the common conditions shown in Table 3 (deposition cycle) below using the PEALD apparatus illustrated in FIG. 1A and a gas supply system (FPS) illustrated in FIG. 2 with the specific conditions and sequence indicated in Table 4.

TABLE 3
(the numbers are approximate)
Common Conditions for Deposition Cycle

| | |
|---|---|
| Substrate temperature | 350° C. |
| Pressure | 400 Pa |
| Carrier gas | Ar |
| Dilution gas | Ar |
| Flow rate of carrier gas (continuous) | 2000 sccm |
| Flow rate of dilution gas (continuous) | 500 sccm |
| RF power pulse | 5 sec |
| Purge after RF power pulse | 1 sec |

TABLE 4
(the numbers are approximate)

| | | Reactant | RF | Feed pulse/ |
|---|---|---|---|---|
| | Precursor | (flow rate) | [W] | Purge [sec] |
| *1 | Trisilylamine | NH₃ (2 slm) | 100 | 0.1/1 |
| *2 | Trisilylamine | H₂/N₂ (1/1 slm) | 100 | 0.1/1 |
| 3 | Trischlorotrisilylamine | NH₃ (2 slm) | 100 | 0.5/1 |
| 4 | Trischlorotrisilylamine | H₂/N₂ (1/1 slm) | 100 | 0.5/1 |
| 5 | Monochlorotrisilylamine | NH₃ (2 slm) | 100 | 0.1/1 |
| 6 | Monochlorotrisilylamine | H₂/N₂ (1/1 slm) | 100 | 0.1/1 |
| 7 | tetramethylchlorodisilazane | NH₃ (2 slm) | 200 | 0.5/1 |
| 8 | tetramethylchlorodisilazane | H₂/N₂ (1./1 slm) | 200 | 0.5/1 |

In Table 4, the Example numbers with “*” indicate comparative examples. Each obtained film was evaluated. Table 5 shows the results of evaluation.

TABLE 5
(the numbers are approximate)

| | | Sidewall | Bottom | | | |
|---|---|---|---|---|---|---|
| | GPC | Coverage | Coverage | 100:1 DHF | 100:1 DHF | |
| | (nm/cycle) | @AR3 (%) | @AR3 (%) | WERR@TOX | Sidewall/Bottom | Film |
| *1 | 0.01 | 65 | 85 | 0.4 | 1.2 | SiNH |
| *2 | 0.009 | 67 | 80 | 0.3 | 1.1 | SiNH |
| 3 | 0.04 | 94 | 95 | 0.3 | 1.1 | SiNH |
| 4 | 0.03 | 97 | 97 | 0.3 | 1.2 | SiNH |
| 5 | 0.02 | 92 | 91 | 0.3 | 1.1 | SiNH |
| 6 | 0.02 | 93 | 92 | 0.3 | 1.1 | SiNH |
| 7 | 0.02 | 92 | 91 | <0.1 | 1.1 | SiNCH |
| 8 | 0.02 | 95 | 95 | <0.1 | 1.0 | SiNCH |

In Table 5, “GPC” represents growth rate per cycle, “Sidewall Coverage@AR3” represents a percentage of thickness of film deposited on a sidewall relative to thickness of film deposited on a blanker surface at a trench having an aspect ratio of 3, “Bottom Coverage@AR3” represents a percentage of thickness of film deposited on a bottom surface relative to thickness of film deposited on a blanket surface at a trench having an aspect ratio of 3, “100:1 DHF WERR@TOX” represents wet etch rate using a diluted HF solution at a 1% concentration relative to that of thermal oxide film, “100:1 DHF Sidewall/Bottom” represents a ratio of wet etch rate at a sidewall to wet etch rate at a bottom surface using a diluted HF solution at a 1% concentration relative to that of thermal oxide film, and “Film” represents compositions of the film.

In the above examples, precursors were evaluated, wherein at least one of the terminal groups of a silylamine or silazane having a Si—N—Si skeleton or

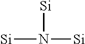

skeleton was terminated with a halogen group. The reactant was either NH₃ or H₂/N₂ considering reactivity with a halogen group. As a result, it was confirmed that the film was either SiNH or SiNCH, and the type of reactant did not substantially affect GPC, and when the precursor contained a halogen group (Examples 3 to 8), GPC was as high as 0.02 to 0.04 nm/cycle, whereas when the precursor did not contain a halogen group (Examples 1 and 2), GPC was at most 0.01 nm/cycle. Further, both the sidewall coverage and the bottom surface coverage were over 90% when the precursor contained a halogen group (Examples 3 to 8), whereas the sidewall coverage was less than 70% and the bottom surface coverage was at most 85% when the precursor did not contain a halogen group (Examples 1 and 2). Additionally, chemical resistance of the film was not degraded even on the sidewall in Examples 3 to 8.

When the precursor has a bond wherein two or three Si atoms are attached to N, at least one of which Si atoms is terminated by a halogen group, nitridization of the film can be accomplished without highly depending on a plasma. If nitridization depends predominantly on a plasma as in conventional precursors, not only step coverage but also film quality will often suffer, e.g., film quality on a blanket surface (a top surface in which a trench is formed) and a bottom surface will often be different, and film quality on a sidewall will often be unsatisfactory, especially when a patterning size is reduced and a deposition temperature is lowered. For example, when a trench has an opening size of 50 nm and a depth of 125 nm (an aspect ratio is approximately 2), even when a conventional precursor is used, a wet etch rate of film on a sidewall and that of film on a blanket surface are about the same; however, when a trench has an opening size of 30 nm and a depth of 100 nm (an aspect ratio is approximately 3), when the conventional precursor is used, a wet etch rate of film on a sidewall is often twice higher than that of film on a blanket surface. Further, when a deposition temperature is lowered, e.g., 300° C. and 200° C., a wet etch rate of film becomes three and five times higher, respectively, than that of film deposited at a temperature of 400° C. or higher. According to embodiments of the present invention, the above problems can effectively be resolved where a trench has an opening size of less than 50 nm and an aspect ratio of 3 or higher, and a deposition temperature is lower than 400° C.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A method for forming a SiN or SiCN film in a trench on a substrate by plasma-enhanced atomic layer deposition (PEALD) conducting one or more process cycles, each process cycle comprising:
(i) feeding a precursor in a pulse to a reaction space where the substrate is placed, said precursor having a Si—N—Si bond in its skeletal structure to which at least one halogen group is attached; and
(ii) applying RF power to the reaction space in the presence of a reactant gas and in the absence of any precursor to form a monolayer constituting a SiN or SiCN film,
wherein the precursor is fed in a pulse to the reaction space using a flow-pass system (FPS), auto-pressure regulator (APR), or a bottle-out control system (BTO), wherein a gas phase of the precursor is merged into a flow of carrier gas upstream of the reaction space.

2. The method according to claim 1, wherein the reactant gas is fed continuously to the reaction space throughout each process cycle.

3. The method according to claim 1, wherein the Si—N—Si bond of the precursor is a 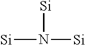
bond.

4. The method according to claim 1, wherein the precursor is one or more compounds selected from the group consisting of: 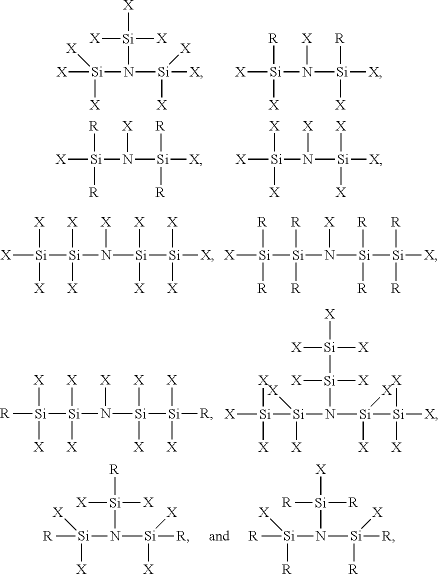
wherein X is H, Cl, F, I, or Br, provided that at least one X in each compound is Cl, F, I, or Br; and R is a chained or cyclic hydrocarbon or nitro hydrocarbon.

5. The method according to claim 1, wherein the reactant gas is one or more gases selected from the group consisting of H₂, NH₃, N₂, NxHy (x and y are integers), and NxCyHz (x, y, and z are integers).

6. The method according to claim 5, wherein the reactant gas is a mixture of _{N2} and _{H2}, or N_{H3}.

7. The method according to claim 1, wherein a noble gas is continuously fed to the reaction space throughout the process cycle.

8. (canceled)

9. The method according to claim 1, further comprising exposing the SiN or SiCN film on the substrate to a hydrogen-containing plasma after the PEALD process, to remove a halogen group, if any, remaining in the SiN or SiCN film.

10. The method according to claim 1, wherein each process cycle further comprises exposing the monolayer on the substrate to a hydrogen-containing plasma to remove a halogen group, if any, remaining in the monolayer.

11. The method according to claim 1, wherein each process cycle further comprises a purging step between steps (i) and (ii), and between steps (ii) and (i) if the process cycle is repeated.

12. The method according to claim 1, wherein a sidewall coverage and a bottom coverage are 90% or higher, wherein the sidewall coverage is defined as a ratio of thickness of film on a sidewall of the trench to thickness of film on a blanket surface of the trench, and the bottom coverage is defined as a ratio of thickness of film on a bottom of the trench to thickness of film on the blanket surface of the trench.
